(19) United States
(12) Patent Application Publication
(10) Pub. No.: US 2010/0149000 A1
(43) Pub. Date: Jun. 17, 2010

(54) OPERATOR CONTROL APPARATUS HAVING AT LEAST ONE PRESSURE-OPERATED SWITCH

(75) Inventor: Uwe Heimann, Wangen (DE)

Correspondence Address: LERNER GREENBERG STEMER LLP, P O BOX 2480, HOLLYWOOD, FL, 33022-2480, US

(73) Assignee: DIEHL AKO STIFTUNG & CO. KG, Wangen (DE)

(21) Appl. No.: 12/622,526

(22) Filed: Nov. 20, 2009

(30) Foreign Application Priority Data
Dec. 13, 2008 (DE) 10 2008 062 216.8

(51) Int. Cl. H03K 17/94

(52) U.S. Cl. 341/34

(57) ABSTRACT

An operator control apparatus has at least one pushbutton switch, and can be used, for example, in an operator control panel for an electronic domestic appliance. The operator control apparatus further has a support element, a pressure-sensitive transmission element with at least one sensor area which corresponds to the at least one pushbutton switch and is connected to the support element by a first adhesive layer, and a covering layer which faces the user side. The covering layer is connected to the transmission element by a second adhesive layer, with the second adhesive layer being soft and having an adhesive layer region in the region of the at least one sensor area of the transmission element. The adhesive layer region is smaller than the sensor area and is at least partially separated from the rest of the second adhesive layer by at least one cutout.

### CROSS-REFERENCE TO RELATED APPLICATION

This application claims the priority, under 35 U.S.C. §119, of German application DE 10 2008 062 216.8, filed Dec. 13, 2008; the prior application is herewith incorporated by reference in its entirety.

### BACKGROUND OF THE INVENTION

### Field of the Invention

The present invention relates to an operator control apparatus having at least one pressure-operated switch, as may be used, for example, in an operator control panel for an electronic domestic appliance.

Pushbutton switches which use the piezo effect are known. Pushbutton switches such as these contain a piezoelectric element which is arranged between two electrodes. When a pressure or a force is exerted on the piezoelectric element, a charge is released at the two electrodes, the charge being proportional to the force exerted. Operation of the pushbutton switch can therefore be detected by measurement of the charge, with the necessary operating distance being very short.

The use of pushbutton switches such as these with a pressure-sensitive transmission element has a number of advantages over conventional key-operated switches. On account of the minimal operating distances, mechanically moving parts are not subject to wear, and the key-operated switch can be configured to be simple and mechanically robust. Furthermore, no apertures or projections and/or recesses are required in the associated operator control panels, for example of the electronic domestic appliances, and therefore the pushbutton switch is arranged so as to be moistureproof, and the operator control panel can be cleaned easily.

It is known from the prior art for a so-called piezo film, for example, to be used as the pressure-sensitive transmission element for a pushbutton switch of this type. In a piezo film, a piezoelectric layer structure is produced, for example by screen printing, in a plurality of steps on a plastic film, with the piezo crystals being printed on, for example, in the form of a piezo lacquer. The electrodes via which the electrical charge generated by the piezo crystals is tapped off are in this case arranged between the layers of the multilayer structure, for example by being printed on.

Electronic domestic appliances and the like require an operator control apparatus which is very compact, is convenient to install and is also intended to have an integration level that is as high as possible.

Published, non-prosecuted European patent application EP 0 502 452 A1 discloses a piezoelectric keyboard. Furthermore, a light-emitting film, which is connected to the two adjacent components in each case by an overlay adhesive layer, is arranged between the piezo film and the transparent front panel in the case of this conventional keyboard.

In conventional operator control apparatuses of this type, the piezo film is usually connected to the covering layer by a hard and inflexible adhesive layer in order to ensure reliable transmission of even very short operating distances from the covering layer to the piezo film situated beneath it. The disadvantages of this configuration include deformation problems for the operator control apparatus under the influence of temperature and moisture, these problems arising on account of the different components of thermal expansion of the materials of the covering layer and the piezo film.

Therefore, the applicant has already proposed, in published, non-prosecuted German patent application No. 10 2007 054 778.3, corresponding to U.S. patent publication No. 20090128375 A, an operator control apparatus in which the adhesive layer between the covering layer and the piezo film is soft and a force-transmission element, for example in the form of a plunger which is connected to the covering layer, is arranged between the covering layer and the sensor area of the piezo film within a space which is cut out from the adhesive layer. While the flexible adhesive layer compensates for the different thermal expansions of the adjacent components, the rigid force-transmission element ensures transmission even of very short operating distances from the covering layer to the piezo film.

### SUMMARY OF THE INVENTION

It is accordingly an object of the invention to provide an operator control apparatus having at least one pressure-operated switch which overcomes the above-mentioned disadvantages of the prior art devices of this general type, which operator control apparatus has good thermal functional stability.

The operator control apparatus has at least one pushbutton switch. According to the invention it further has a support element, a pressure-sensitive transmission element with at least one sensor area which corresponds to the at least one pushbutton switch and the transmission element is connected to the support element by a first adhesive layer, and a covering layer which faces a user side. The covering layer is connected to the transmission element by a second adhesive layer. The second adhesive layer is soft and has an adhesive layer region in the region of the at least one sensor area of the transmission element. The adhesive layer region is smaller than the sensor area and is at least partially separated from the rest of the second adhesive layer by at least one cutout.

The configuration of the operator control apparatus with a support element, transmission element and covering layer produces a very flat structure. The operator control apparatus of this configuration can be prefabricated and therefore can be installed in a simple manner, as one unit, for example, in an operator control panel of an electronic domestic appliance.

The transmission of the pressure applied by a finger to the covering layer of the operator control apparatus to the transmission element actually requires a stiff and inflexible connection over an area between these two elements. However, because the materials which are used for these elements generally have different coefficients of thermal expansion, this can lead to temperature-dependent stressing and/or deformation of, and in some circumstances even to damage to, the physical structure. If a soft and/or flexible second adhesive is used between the transmission element and the covering layer, it is possible to compensate for and/or to reduce these different thermal expansions of the components which are connected to one another.

In order to allow the short or even very short operating distances to be transmitted from the covering layer to the transmission element despite the soft adhesive connection, the second adhesive layer is configured in such a way that it has an adhesive layer region in the region of the at least one sensor area of the transmission element. The adhesive layer region is smaller than the sensor area and is at least partially separated from the rest of the second adhesive layer by at least one cutout. The adhesive-free cutout around the sensor area adhesive layer region reduces the damping effect of the adhesive layer, and therefore the distances can be transmitted more directly. Therefore, a separate, rigid or inflexible force-transmission element and/or distance-transmission element are/is not required in the refinement of the second adhesive layer according to the invention.

In addition, the covering layer is connected directly to the respective sensor area of the transmission element by the central adhesive layer region of the second adhesive layer, and therefore the transmission element can follow the operating distance of the covering layer directly and on both sides. The distance is therefore transmitted independently of a prestress in the transmission element.

In one embodiment of the operator control apparatus according to the invention, the sensor area adhesive layer region is arranged substantially centrally in relation to the sensor area of the transmission element situated beneath it and/or the at least one cutout of the second adhesive layer can substantially annularly surround the sensor area adhesive layer region.

In one refinement of the invention, the support element has a cutout on that side which is averted from the transmission element, and the operator control apparatus is also provided with a printed circuit board which is inserted into the cutout in the support element, preferably is substantially fully accommodated therein. As a result, it is possible for the operator control apparatus, including the printed circuit board, to be of extremely flat construction.

In a further refinement of the invention, the operator control apparatus can have at least one fixing element for fixing the operator control apparatus to an operator control panel. The at least one fixing element contains, for example, a third adhesive layer and/or a latching apparatus.

In yet another refinement of the invention, the operator control apparatus also has at least one display element (light-emitting diode, display), which is likewise integrated in a compact and flat form in the support element.

In a preferred advantageous alternative, the pressure-sensitive transmission element of the operator control device is a piezo element, a piezo (sensor) film, or a strain gauge. In this case, the operator control apparatus preferably contains a large number of pushbutton switches which are based on the piezo effect or on the strain-measuring principle. In a particular refinement, it is also possible to use different transmission elements in one operator control device.

The operator control apparatus of the invention as described above can be used in a particularly advantageous manner in an operator control panel for an electronic domestic appliance; however, the invention is not intended to be restricted to this application.

Other features which are considered as characteristic for the invention are set forth in the appended claims.

Although the invention is illustrated and described herein as embodied in an operator control apparatus having at least one pressure-operated switch, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a diagrammatic, perspective view of an operator control apparatus, which is inserted into an operator control panel, according to the invention;

FIG. 2 is an exploded, perspective view of the operator control apparatus according to one exemplary embodiment of the invention;

FIG. 3 is a diagrammatic, partial section view of the operator control apparatus shown in FIG. 2, in an installed state;

FIG. 4 is a diagrammatic, partial section view of the operator control apparatus shown in FIG. 2, in the installed state; and

FIG. 5 is a diagrammatic, plan view of a second adhesive layer of the operator control apparatus shown in FIG. 2.

### DETAILED DESCRIPTION OF THE INVENTION

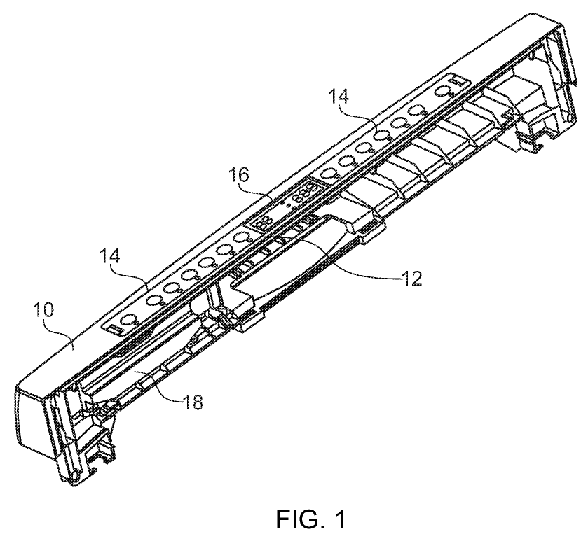

Referring now to the figures of the drawing in detail and first, particularly, to FIG. 1 thereof, there is shown, by way of example, an operator control panel 10 for an electronic domestic appliance (for example an oven, a hob, a washing machine, a dryer, a dishwasher etc.); however, the invention is not intended to be restricted to this application.

On that side which faces the user (at the top in FIG. 1), the operator control panel 10 has a cutout into which an operator control apparatus (or operator control and display apparatus, or input/output apparatus) 12 is inserted, the operator control apparatus having two input regions 14, each having a plurality of pushbutton switches and a central display region 16. FIG. 1 also shows an electronic controller 18 of the domestic appliance, which electronic controller is connected to the operator control apparatus 12 via an appropriate non-illustrated connection cable.

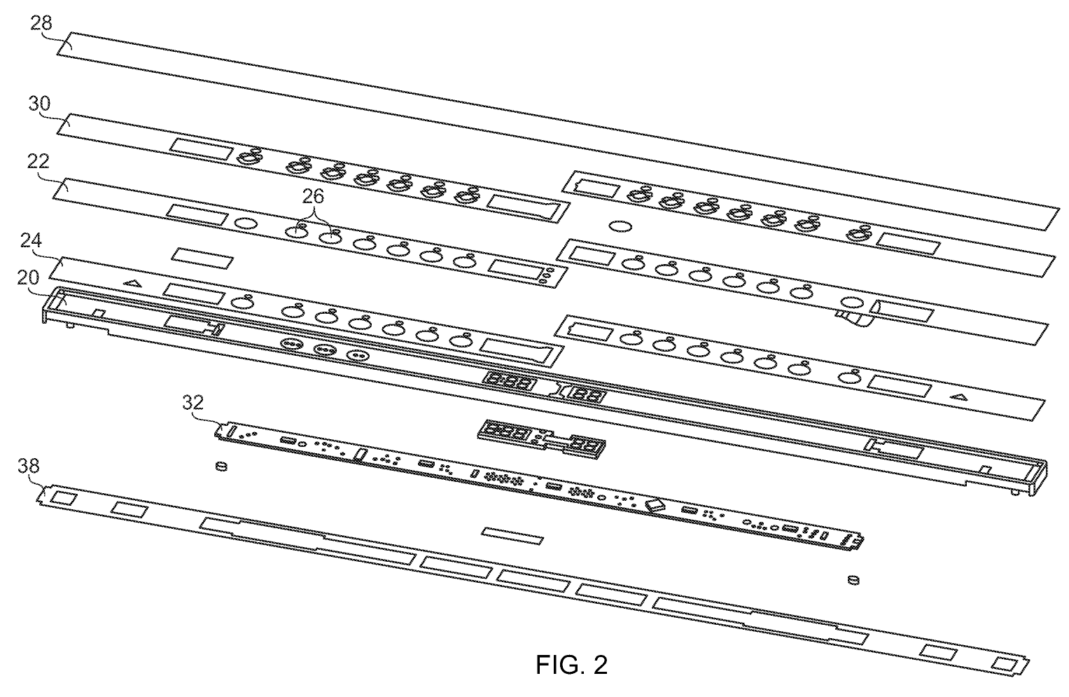

An exemplary embodiment of an operator control apparatus 12 according to the invention will now be described in more detail with reference to FIGS. 2 to 5. In comparison with the basic structure illustrated in FIG. 1, this exemplary embodiment does not have a display region 16. However, it goes without saying that the operator control apparatus 12 shown in FIGS. 2 to 5 can be retrofitted, without problems, with a display region 16 of this type having a corresponding display element.

The operator control apparatus 12 contains a support element 20 containing, for example, plastic (for example PMMA), with the dimensions of the support element generally determining the size of the operator control apparatus 12. On that side (at the top in FIG. 2) of the support element 20 which faces the user, two piezo (sensor) films 22 are arranged in two input regions 14 of the operator control apparatus 12 and are connected to the support element 20 by a first adhesive layer 24. The first adhesive layer 24 usually forms a flexible and soft connection over an area between the support element 20 and the piezo films 22.

In principle, any desired piezo films may be used as piezo films 22; the invention is not restricted to any specific type. The piezo films 22 are each a multilayer piezoelectric element which produces a voltage, which can be measured at the electrodes, when a pressure or a force is exerted, as already explained in the introductory part of the description. The piezo films 22 each have a plurality of sensor areas 26, the number and arrangement of which correspond to the desired pushbutton switches of the operator control apparatus 12.

A strain gauge 22 or a combination of a piezo film 22 and a strain gauge 22 can also be used as an alternative to the piezo film 22.

A covering layer 28 is provided on that side (at the top in FIG. 2) of the piezo films 22 which faces the user, the covering layer 28 being connected to the two piezo films 22 by a second adhesive layer 30 in each case. The covering layer 28 is in the form of a film, for example containing metal, and is used on the one hand as an operating surface to which the user can apply pressure in order to operate a corresponding pushbutton switch at the position of the sensor area 26 of the piezo film 22, the covering layer 28 identifying to the user the individual pushbutton switches on the basis of the positions of the sensor areas 26 of the piezo films 22, and finally being used as a design element for the operator control panel 10.

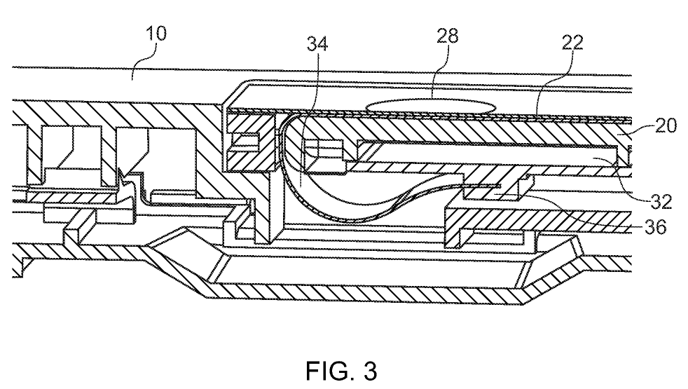

Furthermore, the operator control apparatus 12 has a printed circuit board 32 with evaluation and control electronics for the operator control apparatus, which printed circuit board is inserted into, and/or is preferably substantially completely accommodated in, a cutout on that side (at the bottom in FIG. 2) of the support element 20 which is averted from the user. The printed circuit board 32 is usually firmly clamped in the corresponding recess in the support element 20, or is optionally also fixed by adhesive points. As illustrated in FIG. 3, the piezo films 22 are each connected via a connection cable 34 to a corresponding connection/plug 36 on the lower face of the printed circuit board. The printed circuit board 32 is, in turn, connected to the electronic controller 18 (FIG. 1) via a suitable connection cable, although this is not illustrated in the figures.

The above-described layer structure of the operator control apparatus 12, including the piezo films 22 and the printed circuit board 32, provides an operator control apparatus of extremely flat construction and having a high degree of integration. The operator control apparatus 12 having a large number of pushbutton switches can be installed in advance as one unit, and can then be inserted into the operator control panel 10, thus considerably simplifying the installation of the pushbutton switches. At the same time, the operator control apparatus 12 also performs a design function, if the covering layer(s) 28 is/are of suitable design.

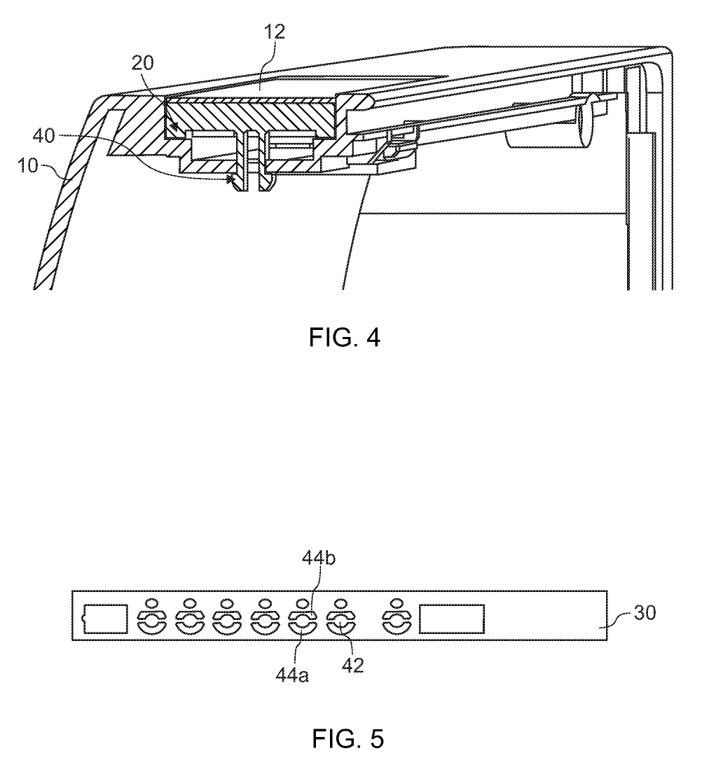

In order to fix the prefabricated operator control apparatus 12 in the operator control panel 10, a third adhesive layer 38 may be provided on that side of the operator control apparatus 12 which is averted from the user (see FIG. 2). As an alternative or in addition, the support element 20 is formed with at least one latching apparatus 40 which can be used to latch the operator control apparatus 12 into corresponding latching recesses in the operator control panel 10, as is illustrated in FIG. 4.

As mentioned above, the piezo films 22 are connected directly and firmly to the covering layer 28 by the second adhesive layers 30. In contrast to the conventional operator control apparatuses of this type, the second adhesive layers 30 are not hard and inflexible but, according to the present invention, instead form a soft and flexible connection over an area between the two components.

On account of this flexible connection between the piezo films 22 and the covering layer 28, different thermal expansions of these two components of the operator control apparatus 12, which thermal expansions are caused by the different materials of the components, can advantageously be compensated for or at least considerably reduced, and therefore no heat-dependent stressing or deformation is produced between the two components.

However, the flexibility of the second adhesive layers 30 reduces the transmission of the short operating distances from the covering layer 28 to the sensor areas 26 of the piezo films 22, and is therefore inconsistent with the actual switching function of the pushbutton switches. Whereas this disadvantage is remedied in published non-prosecuted German patent application No. 10 2007 054 778.3 by the arrangement of a force-transmission element in each case between the piezo film 22 and the covering layer 28 in the region of a sensor area 26, the force-transmission element being positioned in a corresponding cutout in the second adhesive layer 30 and transmitting the pressure forces from the covering layer 28, which is used as an operating surface, to the pressure-sensitive piezo film 22, the present invention provides a special second adhesive layer 30, on account of which the additional force-transmission elements can be dispensed with.

As illustrated in the plan view shown in FIG. 5, the second adhesive layer 30 has, in the region of a corresponding sensor area 26 of the piezo film 22 situated beneath it, an adhesive layer region 42 which is separated from the rest of the second adhesive layer 30 by two cutouts 44a, 44b. In this case, this sensor area adhesive layer region 42 is considerably smaller than the respective sensor area 26 of the piezo film 22. The adhesive layer regions 42, which are substantially in the form of points, for example, are preferably an integral constituent part of the second adhesive layer 30 in this case. In addition, the cutouts 44a, 44b are also situated in the region of the sensor area 26 of the piezo film 22.

In this exemplary embodiment, the sensor area adhesive layer region 42 is in each case arranged substantially centrally in relation to the respective piezo film sensor area 26 and the two cutouts 44a, 44b are arranged substantially annularly around the central sensor area adhesive layer region 42. It goes without saying that it is also possible, in principle, to arrange the adhesive layer region 42 off-center, to provide more than only one adhesive layer region 42 for a piezo film sensor area 26, to arrange only one or more than two cutouts 44a, 44b around the adhesive layer region 42 and/or to choose other sizes/shapes/arrangements for the adhesive layer regions 42 and/or for the cutouts 44a, 44b.

As mentioned, the flexible second adhesive layer 30 actually reduces the transmission of the very short operating distances of the cover layer 28 to the sensor areas 26 of the piezo films 22. In order to nevertheless ensure the pushbutton function, the second adhesive layers 30 are formed in the manner described above. In this case, the cutouts 44a, 44b reduce the damping effect of the flexible second adhesive layer 30, and therefore the distances can be transmitted more directly from the covering layer 28 to the sensor areas 26 of the piezo films 22. Therefore, a separate, rigid or inflexible force-transmission element and/or distance-transmission element is not required in this embodiment of the second adhesive layers 30.

In addition, the covering layer 28 is connected directly to the respective sensor area 26 of the piezo film 22 by the central adhesive layer region 42 of the second adhesive layer 30, and therefore the piezo film 22 can follow the operating distance of the covering layer 28 directly and on both sides. The distance is therefore transmitted independently of a prestress in the piezo (sensor) films 22.

In particular, the printed piezo films 22 with the adhesive layers 24, 30 on both sides can be used for the operator control apparatus 12 of the invention.

As is illustrated in FIG. 1, the operator control apparatus 12 can also have the display region 16, in addition to the two input regions 14, in each of which a piezo film 22 is arranged in order to form the plurality of pushbutton switches. A display element, for example in the form of a display with a 7-segment display, can be arranged in the display region 16, on that side of the support element 20 which is averted from the user, and, for example, a printed display cover 28 containing plastic (for example PMMA) can be adhesively bonded to the support element 20 on that side of the support element 20 which faces the user. The display element may optionally also have only individual light-emitting diodes.

In the exemplary embodiment of FIGS. 2 to 5, the operator control apparatus 12 contains two input regions 14 with pushbutton switches, but the present invention is not restricted only to this embodiment. For example, the operator control apparatus 12 may also contain only one input region 14 or more than two input regions 14, and a plurality of input regions 14 can optionally be arranged next to one another and/or one behind the other. In addition to the input region or regions, it is also possible to provide one or more display regions 16 in the operator control apparatus 12. The number of pushbutton switches in an input region 14 and/or the number of sensor areas 26 on a piezo film 22 are/is also not specifically restricted. Furthermore, each sensor area 26 of the piezo film 22 need not necessarily have an associated pushbutton switch, and therefore, for example, the same piezo films 22 can be used in each case for a plurality of types and models of one domestic appliance with different input regions 14.

In this exemplary embodiment, the piezo films 22 and the first and the second adhesive layers 24, 30 are formed from two parts in accordance with the two input regions 14, whereas the covering layer 28 is formed from one part. It is likewise possible for the piezo films 22 and the adhesive layers 24, 30 also to be formed from one part and/or for the covering layer 28 to be formed from two parts. Furthermore, the piezo films 22, adhesive layers 24, 30 and covering layers 28 can optionally also have more than two subregions, particularly when a plurality of input regions 14 and/or also at least one display region 16 are/is provided.

1. An operator control apparatus, comprising:
at least one pushbutton switch;
a support element;
a first adhesive layer;
a second adhesive layer;
a pressure-sensitive transmission element having at least one sensor area corresponding to said at least one pushbutton switch, said transmission element connected to said support element by means of said first adhesive layer; and
a covering layer facing a user side, said covering layer connected to said pressure-sensitive transmission element by means of said second adhesive layer;
said second adhesive layer being soft and having an adhesive layer region in a region of said at least one sensor area of said pressure-sensitive transmission element, said adhesive layer region being smaller than said sensor area and being at least partially separated from a rest of said second adhesive layer by means of at least one cutout formed therein.

2. The operator control apparatus according to claim 1, wherein said adhesive layer region is disposed substantially centrally in relation to said sensor area of said pressure-sensitive transmission element.

3. The operator control apparatus according to claim 1, wherein said at least one cutout of said second adhesive layer substantially annularly surrounds said adhesive layer region.

4. The operator control apparatus according to claim 1,
wherein said support element has a cutout formed therein on a side which is averted from said pressure-sensitive transmission element; and
further comprising a printed circuit board inserted into said cutout in said support element.

5. The operator control apparatus according to claim 4, wherein said printed circuit board is substantially fully accommodated in said cutout in said support element.

6. The operator control apparatus according to claim 1, further comprising at least one fixing element for fixing the operator control apparatus to an operator control panel.

7. The operator control apparatus according to claim 6, wherein said at least one fixing element contains a third adhesive layer.

8. The operator control apparatus according to claim 6, wherein said at least one fixing element contains a latching apparatus.

9. The operator control apparatus according to claim 1, wherein said pressure-sensitive transmission element is selected from the group consisting of a piezo element, a piezo film and a strain gauge.

10. An electronic domestic appliance, comprising:
an operator control panel; and
an operator control apparatus inserted into said operator control panel, said operator control apparatus containing:
at least one pushbutton switch;
a support element;
a first adhesive layer;
a second adhesive layer;
a pressure-sensitive transmission element having at least one sensor area corresponding to said at least one pushbutton switch, said transmission element connected to said support element by means of said first adhesive layer; and
a covering layer facing a user side, said covering layer connected to said pressure-sensitive transmission element by means of said second adhesive layer;
said second adhesive layer being soft and having an adhesive layer region in a region of said at least one sensor area of said pressure-sensitive transmission element, said adhesive layer region being smaller than said sensor area and being at least partially separated from a rest of said second adhesive layer by means of at least one cutout formed therein.
